(19) United States
(12) Patent Application Publication
(10) Pub. No.: US 2025/0140581 A1
(43) Pub. Date: May 1, 2025

(54) SUBSTRATE PROCESSING APPARATUS AND SUBSTRATE PROCESSING METHOD

(71) Applicant: Tokyo Electron Limited, Tokyo (JP)

(72) Inventors: Masami YAMASHITA, Koshi City, Kumamoto (JP); Tatsuya NAGAMATSU, Koshi City, Kumamoto (JP)

(21) Appl. No.: 18/924,328

(22) Filed: Oct. 23, 2024

(30) Foreign Application Priority Data
Nov. 1, 2023 (JP) 2023-187835

(51) Int. Cl. H01L 21/67; G05B 19/4099; H01L 21/306; H01L 21/677

(52) U.S. Cl. CPC H01L 21/67086; G05B 19/4099; H01L 21/30604; H01L 21/67757; G05B 2219/45031

(57) ABSTRACT

A substrate processing apparatus includes: an immersion processor for collectively immersing a set of one or more substrates in a processing liquid and process the set; a standby bath for immersing the set in a rinsing liquid; a first transferer for transferring the set from the immersion processor to the standby bath; a first deliverer for accommodating the set after the immersion in the standby bath; a second transferer for transferring the set from the standby bath to the first deliverer; a single-wafer processor for processing the substrates one by one; a second deliverer for accommodating the substrates processed by the single-wafer processor; a third transferer for transferring the substrates one by one between the first and second deliverers and the single-wafer processor; and a controller for controlling the above-described components to execute a series of substrate processes.

### CROSS-REFERENCE TO RELATED APPLICATION

This application is based upon and claims the benefit of priority from Japanese Patent Application No. 2023-187835, filed on Nov. 1, 2023, the entire contents of which are incorporated herein by reference.

### TECHNICAL FIELD

The present disclosure relates to a substrate processing apparatus and a substrate processing method.

### BACKGROUND

In the related art, there is known a substrate processing apparatus including both a single-wafer type processor (single-wafer processor) which processes substrates such as semiconductor wafers one by one, and a batch type processor (immersion processor) which collectively processes a plurality of substrates by immersing the substrates in a processing liquid.

### PRIOR ART DOCUMENT

### Patent Document

Patent Document 1: Japanese Laid-Open Patent Publication No. 2016-502275

### SUMMARY

According to one embodiment of the present disclosure, a substrate processing apparatus includes: an immersion processor configured to collectively immerse a set of one or more substrates in a processing liquid and process the set; a standby bath configured to immerse the set processed by the immersion processor in a rinsing liquid and cause the set to be in a waiting state; a first transferer configured to transfer the set from the immersion processor to the standby bath; a first deliverer configured to accommodate the set after being immersed in the rinsing liquid in the standby bath; a second transferer configured to transfer the set from the standby bath to the first deliverer; a single-wafer processor configured to process the one or more substrates included in the set one by one; a second deliverer configured to accommodate the one or more substrates processed by the single-wafer processor; a third transferer configured to transfer the one or more substrates one by one between the first deliverer, the single-wafer processor, and the second deliverer; and a controller configured to control the immersion processor, the standby bath, the first transferer, the first deliverer, the second transferer, the single-wafer processor, the second deliverer, and the third transferer to execute a series of substrate processes including an immersion process performed by the immersion processor, a first transfer process of transferring the set from the immersion processor to the first deliverer via the standby bath, a second transfer process of transferring the one or more substrates from the first deliverer to the single-wafer processor, a single-wafer process performed by the single-wafer processor, and a third transfer process of transferring the one or more substrates from the single-wafer processor to the second deliverer, wherein the controller determines a start timing of the immersion process for a subsequent set, based on a cumulative time of the second transfer process, the single-wafer process, and the third transfer process for the set.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a configuration of a substrate processing system according to an embodiment.

FIG. 2 is a diagram showing a configuration of a chemical liquid bath according to an embodiment.

FIG. 3 is a diagram showing a configuration of a liquid processor according to an embodiment.

FIG. 4 is a flowchart showing a process procedure executed by the substrate processing system according to the embodiment.

FIG. 5 is a diagram showing an example of a timing chart for explaining a process of adjusting a start timing of an immersion process for a subsequent set.

### DETAILED DESCRIPTION

Hereinafter, aspects (hereinafter, referred to as “embodiments”) for embodying a substrate processing apparatus and a substrate processing method according to the present disclosure will be described with reference to the drawings. The present disclosure is not limited to the substrate processing apparatus and the substrate processing method. Further, the respective embodiments may be appropriately combined with each other to the extent that processing contents are not contradictory. In addition, the same parts in the following embodiments will be designated by like reference numerals, and duplicate description thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In addition, in each of the drawings to be referred to below, in order to facilitate ease of understanding the descriptions, an orthogonal coordinate system may be defined in which an X-axis direction, a Y-axis direction, and a Z-axis direction are orthogonal to one another, and the Z-axis positive direction is a vertically upward direction. In addition, a direction of rotation about a vertical axis may be referred to as a 0 direction.

In addition, in the embodiments described below, expressions such as “constant,” “orthogonal,” “vertical,” and “parallel” may be used. These expressions do not necessarily mean strictly “constant,” “orthogonal,” “vertical,” and “parallel.” In other words, each of the above expressions allows for, for example, deviations in manufacturing accuracy and installation accuracy.

In the related art, there is known a substrate processing apparatus including both a single-wafer type processor (single-wafer processor) which processes substrates such as semiconductor wafers one by one, and a batch type processor (immersion processor) which collectively processes a plurality of substrates by immersing the substrates in a processing liquid. In such a substrate processing apparatus, a standby bath may be provided for immersing the immersion-processed substrates in a rinsing liquid and causing the substrates to be in a waiting state.

However, when other substrates have been transferred from a deliverer to the single-wafer processor and processed at a timing when the immersion-processed substrates are transferred to a deliverer of the single-wafer processor via the standby bath, the immersion-processed substrates wait in the standby bath until a process of transferring the other substrates are completed.

When waiting times of a plurality of substrates inside the standby bath are different from each other, variations in processing characteristics between the substrates may increase.

Therefore, in the substrate processing apparatus including the immersion processor and the single-wafer processor, variations in processing characteristics between substrates need to be suppressed.

### Configuration of Substrate Processing System

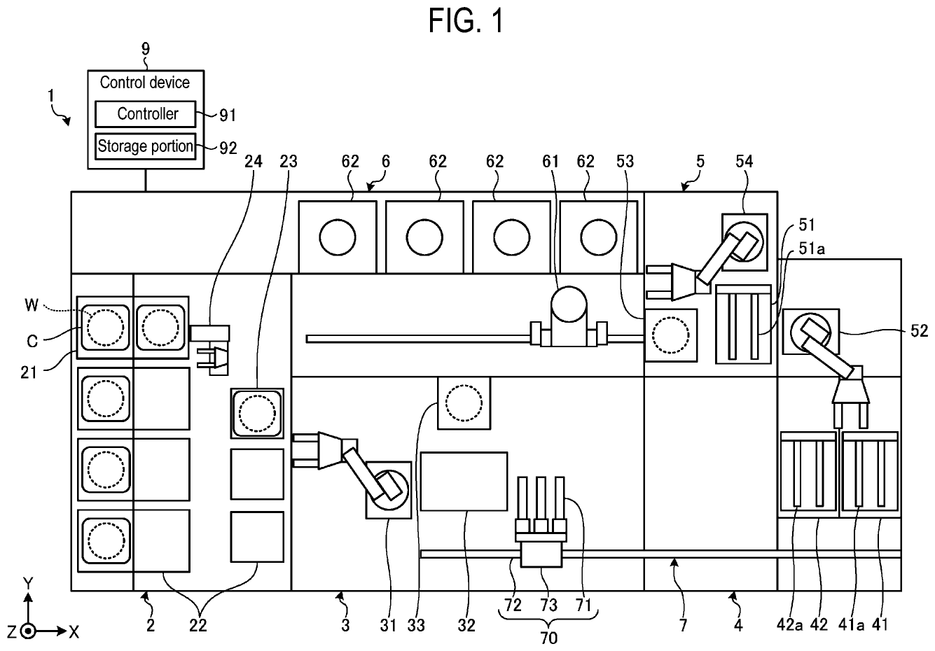

First, a configuration of a substrate processing system 1 (an example of a substrate processing apparatus) according to an embodiment will now be described with reference to FIG. 1. FIG. 1 is a diagram showing the configuration of the substrate processing system according to an embodiment.

As shown in FIG. 1, the substrate processing system 1 includes a loading/unloading part 2, a first interface 3, an immersion processor 4, a second interface 5, a single-wafer processor 6, and a control device 9.

The loading/unloading part 2 includes a load port 21, a stocker 22, a loader 23, and a cassette transfer mechanism 24.

The load port 21 is disposed on a negative side of the loading/unloading part 2 in an X-axis direction. A plurality of load ports 21 (for example, four load ports 21) is disposed in a Y-axis direction. However, the number of the load ports 21 is not particularly limited. A cassette C is placed on the load port 21. The cassette C is a container which accommodates a plurality of substrates W (for example, 25 substrates) arranged vertically in a horizontal posture and is loaded into and unloaded from the load port 21.

A plurality of stockers 22 (for example, four stockers 22) is arranged in the Y axis direction at the center of the loading/unloading part 2 in the X axis direction. The plurality of stockers 22 (for example, two stockers 22) is arranged to be adjacent to the first interface 3 in the Y axis direction on a positive side of the X axis direction of the loading/unloading part 2. The stockers 22 may be arranged in multiple stages in a vertical direction. The stockers 22 temporarily store the cassette C in which the substrates W before cleaning processing are accommodated, or the cassette C, the interior of which is empty after the substrates W have been taken out. The number of the stockers 22 is not particularly limited.

The loader 23 is adjacent to the first interface 3 and is arranged on the positive side of the loading/unloading part 2 in the X axis direction. The cassette C is placed on the loader 23.

The loader 23 is provided with a cover opening/closing mechanism (not shown) for opening and closing a cover of the cassette C. A plurality of loaders 23 may be arranged. The loaders 23 may be arranged in multiple stages in the vertical direction.

The cassette transfer mechanism 24 transfers the cassette C between the load port 21, the stocker 22, and the loader 23. The cassette transfer mechanism 24 is constituted with, for example, a multi-articulated transfer robot.

The first interface 3 is disposed on the positive side of the loading/unloading part 2 in the X-axis direction. The first interface 3 transfers the substrates W between the loading/unloading part 2, the immersion processor 4, and the single-wafer processor 6. The first interface 3 includes a substrate transfer mechanism 31, a lot former 32, and a deliverer 33 (an example of a second deliverer).

The substrate transfer mechanism 31 transfers the substrates W between the cassette C placed on the loader 23, the lot former 32, and the deliverer 33. The substrate transfer mechanism 31 includes a plurality of holders for holding the plurality of substrates W (for example, 25 substrates). The substrate transfer mechanism 31 is constituted with, for example, a multi-articulated robot, and collectively transfers the plurality of substrates W (for example, 25 substrates) using the plurality of holders. The substrate transfer mechanism 31 may change the posture of the plurality of substrates W from the horizontal posture to a vertical posture during transfer.

The lot former 32 is disposed at the center of the first interface 3 in the X-axis direction. The lot former 32 forms a lot including the plurality of substrates W. In the embodiment, the lot is formed by combining a total of 50 substrates W contained in two cassettes C. The lot includes a set of one or more substrates W processed in the immersion processor 4. The number of the substrates W constituting the lot is not limited to 50. For example, the lot may include 100 substrates W.

The deliverer 33 is adjacent to the single-wafer processor 6 and is disposed at the center of the first interface 3 in the Y-axis direction. The deliverer 33 is configured to be capable of accommodating the plurality of substrates W in a horizontal posture in multiple stages. The deliverer 33 receives the substrates W from a third transfer mechanism 61 and temporarily stores the substrates W until the substrates W are delivered to the loading/unloading part 2. The deliverer 33 accommodates the substrates W that have been processed in the single-wafer processor 6.

The immersion processor 4 is disposed on the positive side of the first interface 3 in the X-axis direction. That is, the loading/unloading part 2, the first interface 3, and the immersion processor 4 are disposed in this order from the negative side of the X-axis direction toward the positive side of the X-axis direction. The immersion processor 4 collectively immerses the set of one or more substrates W in a processing liquid and processes the set. One set is composed of one or more substrates W taken out of one lot. The number of the substrates included in one set is equal to or greater than one and equal to or less than the number of a plurality of liquid processors 62 described later in the single-wafer processor 6 (for example, four or fewer substrates). The immersion processor 4 includes a chemical liquid bath 41 and a rinsing liquid bath 42.

The chemical liquid bath 41 and the rinsing liquid bath 42 are arranged in the X-axis direction. For example, the chemical liquid bath 41 and the rinsing liquid bath 42 are arranged in this order from the positive side of the X-axis direction toward the negative side of the X-axis direction. The chemical liquid bath 41 and the rinsing liquid bath 42 are collectively referred to as a processing bath. The number of chemical liquid baths 41 and the number of rinsing liquid baths 42 are not limited to those shown in FIG. 1. For example, the chemical liquid bath 41 and the rinsing liquid bath 42 are one set in FIG. 1 but may be multiple sets.

The chemical liquid bath 41 and the rinsing liquid bath 42 are capable of accommodating one or more substrates W corresponding to at least one set arranged in a vertical posture. Supports 41a and 42a which support one or more substrates W forming a set in a vertical posture are fixed in the chemical liquid bath 41 and the rinsing liquid bath 42, respectively.

The chemical liquid bath 41 stores a chemical liquid for etching (hereinafter, also referred to as an “etching liquid” as an example of a processing liquid) in which the set is immersed. The etching liquid is, for example, an aqueous solution of phosphoric acid (H₃PO₄). The aqueous solution of phosphoric acid selectively etches and removes a silicon nitride film among a silicon oxide film and the silicon nitride film. The etching liquid is not limited to the aqueous solution of phosphoric acid. For example, the etching liquid may be dilute hydrofluoric acid (DHF), buffered hydrofluoric acid (BHF) which is a mixture of hydrofluoric acid and ammonium fluoride, dilute sulfuric acid, a mixture (SPM) of sulfuric acid and hydrogen peroxide, a mixture (SC1) of ammonia, hydrogen peroxide, and water, a mixture (SC2) of hydrochloric acid, hydrogen peroxide, and water, a mixture (TMAH) of tetramethylammonium hydroxide and water, and the like. Details of the chemical liquid bath 41 will be described later.

The rinsing liquid bath 42 stores a processing liquid for rinsing (hereinafter, also referred to as a “first rinsing liquid” as an example of the processing liquid) in which the set is immersed. The first rinsing liquid is pure water for removing the etching liquid from the substrate W and is, for example, deionized water (DIW).

The substrate processing system 1 includes a lot transferer 7. The lot transferer 7 includes a lot transfer mechanism 70 and transfers a lot from the lot former 32 to the immersion processor 4.

The lot transfer mechanism 70 includes a holding body 71, a rail 72, and a moving body 73. The holding body 71 holds the lot in a state in which the plurality of substrates W is in a vertical posture. The rail 72 extends in the X-axis direction from the lot former 32 to the chemical liquid bath 41 of the immersion processor 4. The moving body 73 is provided on the rail 72 and moves the holding body 71 along the rail 72.

The lot transfer mechanism 70 holds the lot formed in the lot former 32 using the holding body 71 and transfers the held lot to the immersion processor 4.

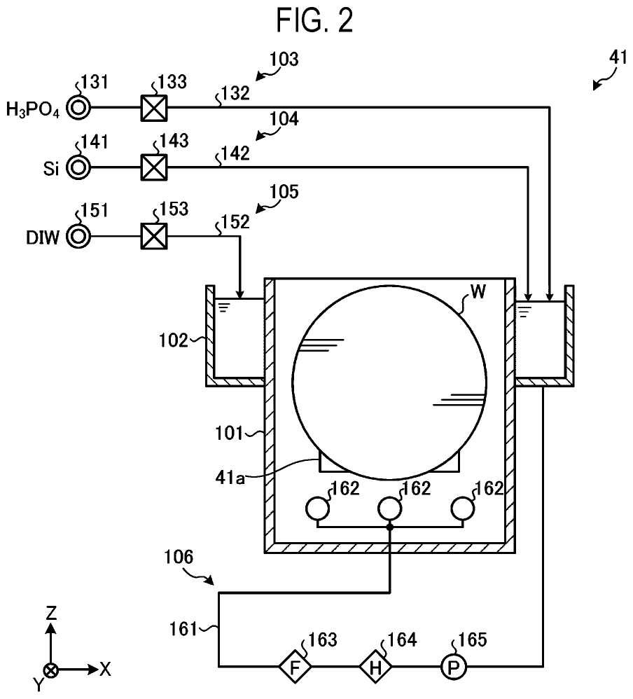

Here, the chemical liquid bath 41 will now be described with reference to FIG. 2. FIG. 2 is a diagram showing a configuration of the chemical liquid bath 41 according to an embodiment.

In the chemical liquid bath 41, an etching process of selectively etching a silicon nitride film among the silicon nitride film (SiN) and a silicon oxide film (SiO₂) formed on the substrate W is performed with a predetermined etching liquid. In this etching process, a solution in which a concentration of silicon is adjusted by adding a silicon (Si)-containing compound to the aqueous solution of phosphoric acid (H₃PO₄) is used as the etching liquid.

As a method of adjusting the concentration of silicon in the etching liquid, a method (seasoning) of dissolving silicon by immersing a dummy substrate in the aqueous solution of phosphoric acid or a method of dissolving a silicon-containing compound such as colloidal silica in the aqueous solution of phosphoric acid may be used. In addition, the concentration of silicon may be adjusted by adding an aqueous solution of the silicon-containing compound to the aqueous solution of phosphoric acid.

As shown in FIG. 2, the chemical liquid bath 41 includes an inner bath 101 and an outer bath 102. The inner bath 101 is a box-shaped bath with an open top and stores an etching liquid therein. A set of one or more substrates W is immersed in the inner bath 101. The outer bath 102 has an open top and is disposed around an upper portion of the inner bath 101. The etching liquid that overflows from the inner bath 101 flows into the outer bath 102.

The chemical liquid bath 41 also includes an aqueous phosphoric acid solution supplier 103, a silicon supplier 104, and a DIW supplier 105.

The aqueous phosphoric acid solution supplier 103 includes an aqueous phosphoric acid solution source 131, an aqueous phosphoric acid solution supply line 132, and a flow rate regulator 133.

The aqueous phosphoric acid solution source 131 supplies an aqueous phosphoric acid solution having a desired phosphoric acid concentration. The aqueous phosphoric acid solution supply line 132 connects the aqueous phosphoric acid solution source 131 and the outer bath 102 to supply the aqueous phosphoric acid solution from the aqueous phosphoric acid solution source 131 to the outer bath 102.

The flow rate regulator 133 is provided in the aqueous phosphoric acid solution supply line 132 to regulate an amount of the aqueous phosphoric acid solution supplied to the outer bath 102. The flow rate regulator 133 includes an on-off valve, a flow rate control valve, a flow meter, and the like.

The silicon supplier 104 includes a silicon source 141, a silicon supply line 142, and a flow rate regulator 143.

The silicon source 141 is a tank for storing an aqueous solution of a silicon-containing compound. The silicon supply line 142 connects the silicon source 141 and the outer bath 102 to supply the aqueous solution of the silicon-containing compound from the silicon source 141 to the outer bath 102.

The flow rate regulator 143 is provided in the silicon supply line 142 to regulate the amount of the aqueous solution of the silicon-containing compound supplied to the outer bath 102. The flow rate regulator 143 includes an on-off valve, a flow rate control valve, a flow meter, etc. As the supply amount of the aqueous solution of the silicon-containing compound is regulated by the flow rate regulator 143, the concentration of silicon of the etching liquid is adjusted.

The DIW supplier 105 includes a DIW source 151, a DIW supply line 152, and a flow rate regulator 153. The DIW supplier 105 supplies DIW to the outer bath 102 in order to replenish moisture evaporated by heating the etching liquid.

The DIW supply line 152 connects the DIW source 151 and the outer bath 102 to supply DIW at a predetermined temperature from the DIW source 151 to the outer bath 102.

The flow rate regulator 153 is provided in the DIW supply line 152 to regulate an amount of DIW supplied to the outer bath 102. The flow rate regulator 153 includes an on-off valve, a flow rate control valve, a flow meter, and the like. As the supply amount of DIW is regulated by the flow rate regulator 153, the temperature of the etching liquid, and concentrations of the phosphoric acid and silicon in the etching liquid are adjusted.

The chemical liquid bath 41 also includes a circulator 106. The circulator 106 circulates the etching liquid between the inner bath 101 and the outer bath 102. The circulator 106 includes a circulation line 161, a plurality of processing liquid supply nozzles 162, a filter 163, a heater 164, and a pump 165.

The circulation line 161 connects the outer bath 102 and the inner bath 101. One end of the circulation line 161 is connected to the outer bath 102, and the other end of the circulation line 161 is connected to the plurality of processing liquid supply nozzles 162 arranged inside the inner bath 101.

The filter 163, the heater 164, and the pump 165 are provided in the circulation line 161. The filter 163 removes impurities from the etching liquid flowing through the circulation line 161. The heater 164 heats the etching liquid flowing through the circulation line 161 to a temperature suitable for an etching process. The pump 165 sends the etching liquid inside the outer bath 102 to the circulation line 161. The filter 163, the heater 164, and the pump 165 are provided in this order from an upstream side.

The circulator 106 sends the etching liquid from the outer bath 102 into the inner bath 101 via the circulation line 161 and the plurality of processing liquid supply nozzles 162. The etching liquid sent into the inner bath 101 overflows from the inner bath 101 and flows backward into the outer bath 102. In this way, the etching liquid circulates between the inner bath 101 and the outer bath 102.

The circulator 106 may boil the etching liquid by heating the etching liquid using the heater 164.

Returning to FIG. 1, the second interface 5 is disposed on a positive side of the immersion processor 4 in the Y-axis direction. The second interface 5 transfers the set of substrates W between the immersion processor 4 and the single-wafer processor 6. The second interface 5 includes a standby bath 51, a first transfer mechanism 52 (an example of a first transferer), a deliverer 53 (an example of a first deliverer), and a second transfer mechanism 54 (an example of a second transferer).

The standby bath 51 is capable of accommodating at least one set of substrates W arranged in a vertical posture. In the standby bath 51, a support 51a for supporting one or more substrates W forming a set in a vertical posture is fixed.

The standby bath 51 stores a processing liquid for rinsing (hereinafter, also referred to as a “second rinsing liquid”) in which the set is immersed. The second rinsing liquid is, for example, DIW. The substrates W are supported in the second rinsing liquid by the support 51a until the substrates W are lifted up from the second rinsing liquid by the second transfer mechanism 54.

The first transfer mechanism 52 has holders. The number of the holders is equal to or greater than one and equal to or less than the number of the liquid processors 62 (for example, four or fewer holders) for holding the substrates W included in the set, respectively, and the number of the substrates W is equal to or greater than one and equal to or less than the number of the liquid processors 62 (for example, four or fewer substrates). The first transfer mechanism 52 is constituted with, for example, a multi-articulated robot, and collectively transfers the set of one or more substrates W using the holders.

The first transfer mechanism 52 receives one set included in the lot transferred to the immersion processor 4 by the lot transfer mechanism 70 described later from the lot transfer mechanism 70 using the holders, and immerses the set in the processing liquid of the immersion processor 4. The first transfer mechanism 52 takes the set out of the immersion processor 4 using the holders, transfers the set to the standby bath 51, and immerses the set in the second rinsing liquid of the standby bath 51.

The deliverer 53 is adjacent to the single-wafer processor 6 and is disposed on a negative side of the second interface 5 in the X-axis direction. The deliverer 53 is configured to be capable of accommodating one or more substrates W forming the set in a horizontal posture. The deliverer 53 receives the substrates W from the second transfer mechanism 54 and temporarily stores the substrates W until the substrates W are delivered to the single-wafer processor 6. The deliverer 53 accommodates the substrates W after the substrates have been immersed in the second rinsing liquid in the standby bath 51. The substrates W accommodated in the deliverer 53 are desirably in a state in which, for example, the surfaces of the substrates W are wet with the second rinsing liquid. In this case, a surface tension of the second rinsing liquid does not act on the substrates W, which makes it possible to suppress collapse of a concave-convex pattern of the substrates W. The deliverer 53 may be arranged in multiple stages (for example, three stages) in the vertical direction (Z-axis direction).

The second transfer mechanism 54 has holders. The number of the holders is equal to or greater than one and equal to or less than the number of the liquid processors 62 (for example, four or fewer holders) for holding the substrates W included in the set, respectively, and the number of the substrates W is equal to or greater than one and equal to or less than the number of the liquid processors 62 (for example, four or fewer substrates). The second transfer mechanism 54 is constituted with, for example, a multi-articulated robot, and collectively transfers the set of one or more substrates W using the holders. The second transfer mechanism 54 may change postures of the one or more substrates W included in the set from a vertical posture to a horizontal posture during transfer.

The second transfer mechanism 54 takes the set immersed in the standby bath 51 out of the standby bath 51 using the holders, changes the postures of the one or more substrates W included in the taken-out set from the vertical posture to the horizontal posture, and then transfers the set W to the deliverer 53.

The single-wafer processor 6 is disposed on the negative side of the second interface 5 in the X-axis direction and on the positive side of the loading/unloading part 2 and the first interface 3 in the Y-axis direction. The single-wafer processor 6 may be disposed in multiple stages (for example, three stages) in the vertical direction (Z-axis direction). The single-wafer processor 6 processes the substrates W one by one. The single-wafer processor 6 includes a third transfer mechanism 61 (an example of a third transferer) and the plurality of liquid processors 62 (four liquid processors in this case).

The third transfer mechanism 61 includes a holding body for holding the substrates W. The third transfer mechanism 61 is capable of moving in the horizontal direction (X-axis direction) and rotating about a vertical axis, and transfers substrates W one by one between the deliverer 53, the liquid processor 62, and the deliverer 33, using the holding body. Specifically, the third transfer mechanism 61 transfers the substrates W from the deliverer 53 to the liquid processor 62 and transfers the substrates W from the liquid processor 62 to the deliverer 33.

The liquid processors 62 are disposed on the positive side of the single-wafer processor 6 in the X-axis direction and on the positive side of the single-wafer processor 6 in the Y-axis direction. The plurality of liquid processors 62 is disposed in the X-axis direction. Distances of the plurality of liquid processors 62 from the deliverer 53 are different from each other. Each of the liquid processors 62 processes one sheet of substrate W with a chemical liquid and dries the processed substrate W.

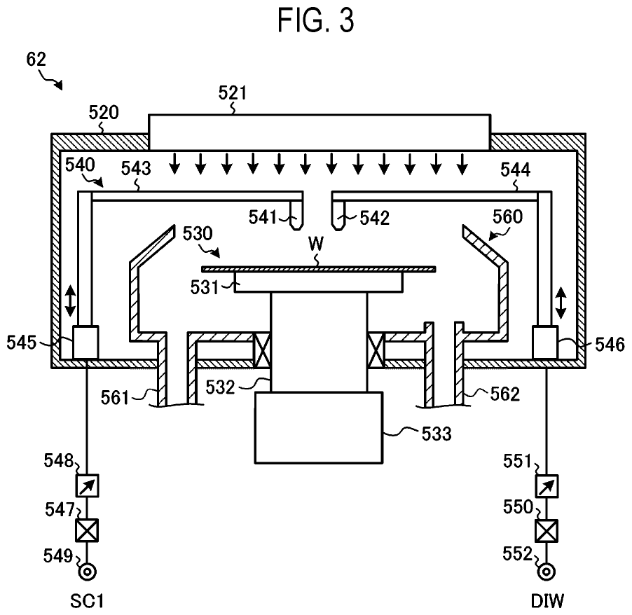

Here, a configuration of the liquid processor 62 will now be described with reference to FIG. 3. FIG. 3 is a diagram showing the configuration of the liquid processor 62 according to an embodiment.

As shown in FIG. 3, the liquid processor 62 includes a chamber 520, a substrate rotator 530, a chemical liquid supplier 540, and a recovery cup 560.

The chamber 520 accommodates the substrate rotator 530, the chemical liquid supplier 540, and the recovery cup 560. A fan filter unit (FFU) 521 is provided in a ceiling portion of the chamber 520. The FFU 521 forms a down-flow inside the chamber 520.

The substrate rotator 530 includes a holder 531, a column 532, and a driver 533, and holds and rotates the substrate W. The holder 531 adsorbs a bottom surface of the substrate W to hold the substrate W horizontally. The holder 531 is not limited to holding the bottom surface of the substrate W and may hold an end portion of the substrate W.

The column 532 is a member extending in the vertical direction, a base portion of which is rotatably supported by the driver 533 and a tip portion of which supports the holder 531 horizontally. The driver 533 rotates the column 532 around the vertical axis.

The substrate rotator 530 rotates the column 532 using the driver 533 to rotate the holder 531 supported by the column 532, thereby rotating the substrate W held by the holder 531.

The chemical liquid supplier 540 supplies a mixture (SC1) of ammonia, hydrogen peroxide, and water, and DIW, as a chemical liquid, to the surface of the substrate W. The chemical liquid supplier 540 includes first and second nozzles 541 and 542, arms 543 and 544 horizontally supporting the first and second nozzles 541 and 542, respectively, and pivoting and lifting mechanisms 545 and 546 for pivoting and lifting the arms 543 and 544, respectively.

The first nozzle 541 is connected to an SC1 source 549 via a valve 547 and a flow rate regulator 548. The second nozzle 542 is connected to a DIW source 552 via a valve 550 and a flow rate regulator 551.

The first nozzle 541 supplies SC1 supplied from the SC1 source 549 to the substrate W. The second nozzle 542 supplies DIW supplied from the DIW source 552 to the substrate W.

The recovery cup 560 is disposed to surround the holder 531 and collects SC1, DIW, and the like scattered from the substrate W with the rotation of the holder 531. A drain port 561 is formed in a bottom portion of the recovery cup 560. The SC1, DIW, and the like collected by the recovery cup 560 are discharged from the drain port 561 outward of the liquid processor 62.

In addition, an exhaust port 562 is formed in the bottom portion of the recovery cup 560 to discharge gas supplied from the FFU 521 outward of the liquid processor 62.

The liquid processor 62 is configured as described above. After a lower surface of the substrate W is adsorbed and held by the holder 531, the holder 531 is rotated by the driver 533 to rotate the substrate W. Thereafter, the liquid processor 62 ejects SC1 from the first nozzle 541 toward the rotating substrate W. Thereafter, the liquid processor 62 ejects DIW from the second nozzle 542 toward the rotating substrate W. As a result, SC1 adhering to the substrate W is washed away by DIW. Thereafter, the liquid processor 62 centrifugally dehydrates the DIW on the substrate W and dries the substrate W by increasing the rotational speed of the substrate W.

The control device 9 is, for example, a computer, and includes a controller 91 and a storage 92. The storage 92 stores programs for controlling various processes executed in the substrate processing system 1. The controller 91 includes a microcomputer equipped with a central processing unit (CPU), a read only memory (ROM), a random access memory (RAM), an input/output port, and the like, and various circuits. The controller 91 controls the operation of the substrate processing system 1 by reading and executing the programs stored in the storage 92.

The programs may be recorded in a non-transitory computer-readable storage medium and installed from the storage medium in the storage 92 of the control device 9. The computer-readable storage medium includes, for example, a hard disk (HD), a flexible disk (FD), a compact disc (CD), a magneto-optical (MO) disk, and a memory card.

### Specific Operation of Substrate Processing System 1

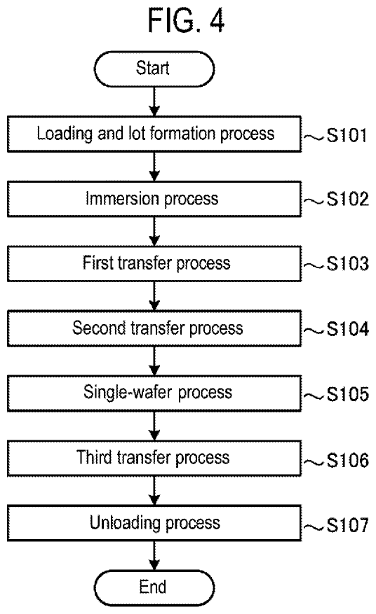

Next, a process procedure executed by the substrate processing system 1 will be described with reference to FIG. 4. FIG. 4 is a flowchart showing the process procedure executed by the substrate processing system 1 according to the embodiment. Each process shown in FIG. 4 is executed under the control of the controller 91.

Herein, a substrate process procedure of a series of processes executed for one set of one or more substrates W is shown as an example.

As shown in FIG. 4, the substrate processing system 1 takes a plurality of substrates W out of each of two cassettes C using the substrate transfer mechanism 31 to form a lot composed of the substrates W (for example, 25 substrates) accommodated in each of the cassettes C (step S101).

The process of step S101 will now be described with reference to FIG. 1. First, the cassette transfer mechanism 24 takes the cassette C out of the load port 21 and places the cassette C on the loader 23. Thereafter, the substrate transfer mechanism 31 takes a plurality of substrates W out of the cassette C placed on the loader 23, changes the posture of the taken-out substrates W from a horizontal posture to a vertical posture, and places the plurality of substrates W in the lot former 32. By repeating this operation twice, the lot is formed in the lot former 32.

Subsequently, the substrate processing system 1 performs an immersion process on the set included in the formed lot (step S102).

Specifically, the lot transfer mechanism 70 receives the lot from the lot former 32 and transfers the lot upward of the chemical liquid bath 41 of the immersion processor 4. Subsequently, the first transfer mechanism 52 receives one set included in the lot transferred upward of the chemical liquid bath 41 from the lot transfer mechanism 70. Then, the first transfer mechanism 52 immerses the received set in an etching liquid stored in the chemical liquid bath 41. Thereafter, the first transfer mechanism 52 takes the set out of the chemical liquid bath 41 and immerses the set in a first rinsing liquid stored in the rinsing liquid bath 42. As a result, the etching liquid adhering to the substrates W is washed away by the first rinsing liquid stored in the rinsing liquid bath 42.

Subsequently, the substrate processing system 1 performs a first transfer process (step S103). The first transfer process is a process in which the first transfer mechanism 52 and the second transfer mechanism 54 take the set out of the immersion processor 4 and transfer the set to the deliverer 53 via the standby bath 51. Specifically, the first transfer mechanism 52 takes the set supported by the support 42a inside the rinsing liquid bath 42 out of the rinsing liquid bath 42, transfers the taken-out set to the standby bath 51, and immerses the set in the second rinsing liquid stored in the standby bath 51. Then, the second transfer mechanism 54 takes the set supported by the support 51a inside the standby bath 51 out of the standby bath 51. Thereafter, the second transfer mechanism 54 changes the posture of one or more substrates W included in the set from a vertical posture to a horizontal posture and places the substrates W on the deliverer 53.

Subsequently, the substrate processing system 1 performs a second transfer process (step S104). The second transfer process is a process in which the third transfer mechanism 61 takes the substrates W one by one out of the deliverer 53 and transfers the substrates W to the liquid processor 62. Specifically, the third transfer mechanism 61 takes the substrates W one by one out of the deliverer 53 and transfers the substrates W to the substrate rotator 530 in the liquid processor 62.

Subsequently, the substrate processing system 1 performs a single-wafer process in the liquid processor 62 (step S105). Specifically, the liquid processor 62 supplies SC1 to an upper surface of the substrate W while rotating the holder 531 of the substrate rotator 530.

Thereafter, the liquid processor 62 supplies DIW to the upper surface of the substrate W. Thus, SC1 adhering to the substrate W is washed away by DIW. Thereafter, the liquid processor 62 performs a drying process that centrifugally dehydrates the DIW on the substrate W and dries the substrate W by increasing the rotational speed of the substrate W.

Subsequently, the substrate processing system 1 performs a third transfer process (step S106). The third transfer process is a process in which the third transfer mechanism 61 takes the substrate W after the drying process out of the liquid processor 62 and transfers the substrate W to the deliverer 33. Specifically, the third transfer mechanism 61 takes the substrate W out of the liquid processor 62 and places the taken-out substrate W on the deliverer 33.

Subsequently, the substrate processing system 1 performs an unloading process of taking the substrate W out of the deliverer 33 and accommodating the substrate W in the cassette C (step S107). Specifically, the substrate transfer mechanism 31 takes the substrate W out of the deliverer 33 and accommodates the substrate W in the cassette C placed on the loader 23. When the unloading process is completed, a series of substrate processes is completed.

In the substrate processing system 1, the above series of substrate processes is sequentially performed on a plurality of sets each including one or more substrates W.

Here, when substrates W of another set have been transferred from the deliverer 53 to the third transfer mechanism 61 at a timing when a set including substrates W after the immersion process is subjected to the first transfer process, the substrates W after the immersion process will wait in the standby bath 51 until the transfer process of the substrates W of another set is completed.

When waiting times at which the plurality of substrates W waits in the standby bath 51 are different from each other, variations in processing characteristics between the substrates W may increase.

Therefore, in the embodiment, a start timing of the immersion process (step S102) for a subsequent set is determined based on a cumulative time of the second transfer process, the single-wafer process, and the third transfer process (steps S104 to S106) for a preceding set.

Thus, it possible to suppress substrates W of another set from being transferred from the deliverer 53 to the third transfer mechanism 61 and being processed at a timing at which a set including substrates W after the immersion process is subjected to the first transfer process. In other words, waiting times of the substrates W after the immersion process are suppressed from occurring, and a difference in the waiting times of the substrates W after the immersion process may be reduced. Therefore, according to the substrate processing system 1 of the embodiment, it is possible to suppress variations in processing characteristics between the substrates W.

### Details of Process of Adjusting Start Timing of Immersion Process for Subsequent Set

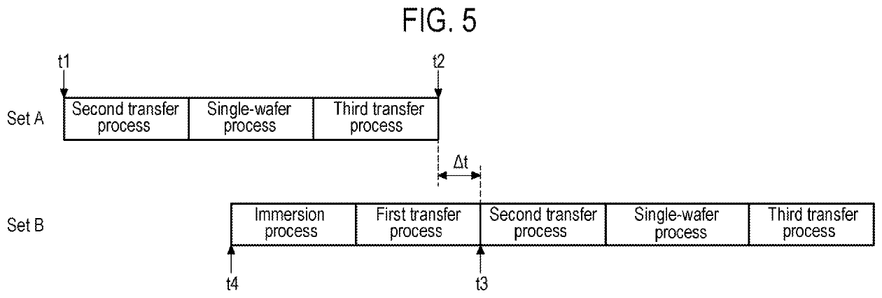

A process of adjusting a start timing of an immersion process for a subsequent set will now be described in detail with reference to FIG. 5. FIG. 5 is a diagram showing an example of a timing chart for explaining the process of adjusting the start timing of the immersion process for the subsequent set. The process shown in FIG. 5 is executed under the control of the controller 91.

Hereinafter, a preceding set will be referred to as “set A” and a subsequent set will be referred to as “set B.” FIG. 5 shows an example of a timing chart in which a series of substrate processes for the set A and a series of substrate processes for the set B are executed in parallel.

For example, it is assumed that, when the third transfer process for the set A is being performed, the start of execution of the immersion process for the set B is possible. In this case, when the execution of the immersion process for the set B is immediately started, a period of the third transfer process for the set A and a completion timing of the first transfer process for the set B may overlap.

Therefore, before the immersion process for the set B is started, the controller 91 determines a start timing of the immersion process for the set B in the following procedure.

First, the controller 91 calculates a cumulative time of the second transfer process, the single-wafer process, and the third transfer process for the set A. Specifically, the controller 91 acquires processing times of the second transfer process and the third transfer process by referring to specification information including a transfer speed of the third transfer mechanism 61 used in the second transfer process and the third transfer process. The controller 91 also acquires a processing time of the single-wafer process by referring to processing recipe information of the series of substrate processes. The specification information and the processing recipe information are stored in, for example, the storage 92. Thereafter, the controller 91 may calculate the cumulative time by adding the processing times of the second transfer process, the single-wafer process, and the third transfer process for the set A. Thus, the controller 91 may specify, as a completion timing t2 of the third transfer process for the set A, a timing when an elapsed time from a start timing t1 of the second transfer process for the set A reaches the cumulative time.

Subsequently, the controller 91 specifies a completion timing of the first transfer process for the set B expected under the assumption that the immersion process for the set B has been started, based on processing times of the immersion process and the first transfer process for the set B. Specifically, the controller 91 acquires a processing time of the immersion process by referring to specification information including transfer speeds of the first transfer mechanism 52 and the second transfer mechanism 54 used in the first transfer process. The controller 91 also acquires a processing time of the immersion process by referring to processing recipe information of a series of substrate processes. Thereafter, the controller 91 specifies, as an expected completion timing t3 of the first transfer processing for the set B, a timing at which the processing times of the immersion process and the first transfer process has elapsed from a timing at which the start of execution of the immersion process for the set B is possible.

Thereafter, the controller 91 determines, as a start timing t4 of the immersion process for the set B, a timing at which an interval At between the completion timing t2 of the third transfer process for the set A and the expected completion timing t3 of the first transfer process for the set B falls within a specified range. Specifically, the controller 91 determines the start timing t4 of the immersion process for the set B so that the interval At falls within the specified range.

In this way, in the substrate processing system 1 according to the embodiment, the start timing of the immersion process for the set B is determined so that the period of the third transfer process for the set A and the completion timing of the first transfer process for the set B do not overlap each other.

Specifically, the controller 91 starts the immersion process for the set B at a timing when the interval At between the completion timing t2 of the third transfer process for the set A and the expected completion timing t3 of the first transfer process for the set B falls within the specified range.

This makes it possible to suppress substrates W of another set from being transferred from the deliverer 53 to the third transfer mechanism 61 and being processed at a timing when a set including substrates W after the immersion process is subjected to the first transfer process. In other words, the occurrence of waiting times of the substrates W after the immersion process may be suppressed, which reduces a difference in the waiting times of the substrates W after the immersion process. Therefore, according to the substrate processing system 1 of the embodiment, variations in processing characteristics between the substrates W may be suppressed.

### Regarding Process of Adjusting Transfer Speed of Substrates in Second Transfer Process

In the substrate processing system 1, in the second transfer process, the substrates W are transferred from the deliverer 53 to the plurality of liquid processors 62, respectively. Since the distances from the deliverer 53 to the plurality of liquid processors 62 are different from each other, when the transfer speeds of the substrates W are the same for the plurality of liquid processors 62, transfer times of the plurality of substrates W transferred from the deliverer 53 to the plurality of liquid processors 62 vary. When the transfer times from the deliverer 53 to the liquid processors 62 vary, a difference may occur in surface states of the substrates W. As a result, variations in processing characteristics of the single-wafer processing (liquid processing) processes between the substrates W may occur.

Therefore, in the substrate processing system 1 according to the embodiment, in the second transfer process, in the case in which the substrates W are transferred from the deliverer 53 to the plurality of liquid processors 62, the transfer speeds of the substrates W are adjusted based on the distances between the deliverer 53 and the liquid processors 62 by controlling the third transfer mechanism 61. For example, the controller 91 reduces the transfer speed of the substrate W transferred to the liquid processor 62 located at a relatively short distance from the deliverer 53 and increases the transfer speed of the substrate W transferred to the liquid processor 62 located at a relatively long distance from the deliverer 53.

Thus, a difference in transfer times of the substrates W transferred from the deliverer 53 to the liquid processors 62 may be reduced. Therefore, according to the substrate processing system 1 of the embodiment, it is possible to suppress the variations in processing characteristics of the single-wafer processing (liquid processing) process between the substrates W caused by the variation in the transfer times from the deliverer 53 to the liquid processors 62.

### Modifications

In the above embodiment, while the liquid processors 62 have been described to perform the drying process using a so-called spin drying method, the drying method is not limited thereto. For example, the substrate W may be dried by surface molecular dry (SMD) processing in which the substrate W is dried by supplying a chemical liquid containing a hydrophobic agent to the upper surface of the substrate W. Further, the substrate W may be dried using a circulating liquid such as isopropyl alcohol (IPA).

In addition, the substrate W may be dried using a supercritical fluid. In this case, the single-wafer processor 6 may include a liquid processor configured to process one substrate W with liquid and a drying processor configured to dry one substrate W with the supercritical fluid. The third transfer mechanism 61 may take the substrate W out of the liquid processor, transfer the substrate W to the drying processor, take the substrate W out of the drying processor, and subsequently, transfer the substrate W to the deliverer 33.

As described above, the substrate processing apparatus according to the embodiment (for example, the substrate processing system 1) includes an immersion processor (for example, the immersion processor 4), a standby bath (for example, the standby bath 51), a first transferer (for example, the first transfer mechanism 52), a first deliverer (for example, the deliverer 53), a second transferer (for example, the second transfer mechanism 54), a single-wafer processor (for example, the single-wafer processor 6), a second deliverer (for example, the deliverer 33), a third transferer (for example, the third transfer mechanism 61), and a controller (for example, the controller 91). The immersion processor collectively immerses the set of one or more substrates (for example, the substrates W) in the processing liquid (for example, the etching liquid or the first rinsing liquid) and processes the set. The standby bath immerses the set processed in the immersion processor in the rinsing liquid (for example, the second rinsing liquid) and causes the set to be in the waiting state. The first transferer transfers the set from the immersion processor to the standby bath. The first deliverer is capable of accommodating the set after being immersed in the rinsing liquid in the standby bath. The second transferer transfers the set to the first deliverer from the standby bath. The single-wafer processor processes the substrates included in the set one by one. The second deliverer is capable of accommodating the substrates processed in the single-wafer processor. The third transferer transfers the substrates one by one between the first deliverer, the single-wafer processor, and the second deliverer. The controller executes the series of substrate processes including the immersion process performed by the immersion processor, the first transfer process of transferring the set to the first deliverer via the standby bath from the immersion processor, the second transfer process of transferring the substrates to the single-wafer processor from the first deliverer, the single-wafer process performed by the single-wafer processor, and the third transfer process of transferring the substrates to the second deliverer from the single-wafer processor, by controlling the above-described respective components. The controller determines the start timing of the immersion process for the subsequent set (for example, the set B), based on the cumulative time of the second transfer process, the single-wafer process, and the third transfer process for the set (for example, the set A).

Specifically, the controller starts the immersion process for the subsequent set at a start timing at which an interval (for example, the interval At) between a timing when an elapsed time from start of the second transfer process for the set reaches the cumulated time and a completion timing of the first transfer process for the subsequent set expected under an assumption that the immersion process for the subsequent set has been started, falls within the specified range.

Therefore, according to the substrate processing apparatus of the embodiment, in a substrate processing apparatus including an immersion processor and a single-wafer processor, it is possible to suppress variations in processing characteristics between substrates.

It should be noted that the embodiments disclosed herein are exemplary in all respects and are not restrictive. Indeed, the embodiments described herein may be embodied in a variety of other forms. The above-described embodiments may be omitted, replaced or modified in various forms without departing from the scope and spirit of the appended claims.

What is claimed is:

1. A substrate processing apparatus, comprising:
an immersion processor configured to collectively immerse a set of one or more substrates in a processing liquid and process the set;
a standby bath configured to immerse the set processed by the immersion processor in a rinsing liquid and cause the set to be in a waiting state;
a first transferer configured to transfer the set from the immersion processor to the standby bath;
a first deliverer configured to accommodate the set after being immersed in the rinsing liquid in the standby bath;
a second transferer configured to transfer the set from the standby bath to the first deliverer;
a single-wafer processor configured to process the one or more substrates included in the set one by one;
a second deliverer configured to accommodate the one or more substrates processed by the single-wafer processor;
a third transferer configured to transfer the one or more substrates one by one between the first deliverer, the single-wafer processor, and the second deliverer; and
a controller configured to control the immersion processor, the standby bath, the first transferer, the first deliverer, the second transferer, the single-wafer processor, the second deliverer, and the third transferer to execute a series of substrate processes including an immersion process performed by the immersion processor, a first transfer process of transferring the set from the immersion processor to the first deliverer via the standby bath, a second transfer process of transferring the one or more substrates from the first deliverer to the single-wafer processor, a single-wafer process performed by the single-wafer processor, and a third transfer process of transferring the one or more substrates from the single-wafer processor to the second deliverer,
wherein the controller determines a start timing of the immersion process for a subsequent set, based on a cumulative time of the second transfer process, the single-wafer process, and the third transfer process for the set.

2. The substrate processing apparatus of claim 1, wherein the controller starts the immersion process for the subsequent set at the start timing at which an interval between a timing when an elapsed time from start of the second transfer process for the set reaches the cumulative time and a completion timing of the first transfer process for the subsequent set expected under an assumption that the immersion process for the subsequent set has been started, falls within a specified range.

3. The substrate processing apparatus of claim 1, wherein the single-wafer processor includes a plurality of single-wafer processors having different distances from the first deliverer, and
wherein, in a case in which the one or more substrates are transferred from the first deliverer to each of the plurality of single-wafer processors in the second transfer process, the controller controls the third transferer to adjust a transfer speed of each of the one or more substrates based on distances between the first deliverer and each of the plurality of single-wafer processors.

4. The substrate processing apparatus of claim 1, wherein the single-wafer processor includes a plurality of liquid processors, each of the plurality of liquid processors being configured to process one substrate with a chemical liquid,
wherein each of the first transferer and the second transferer includes holders, and
wherein the number of the holders is equal to or greater than one and equal to or less than the number of the plurality of liquid processors configured to respectively hold the one or more substrates included in the set, and the number of the one or more substrates is equal to or greater than one and equal to or less than the number of the plurality of liquid processors.

5. The substrate processing apparatus of claim 4, wherein the immersion processor includes:
a processing bath configured to store the processing liquid; and
a first support fixed to the processing bath and configured to support the one or more substrates included in the set,
wherein the standby bath includes a second support fixed to the standby bath and configured to support the one or more substrates included in the set,
wherein the first transferer takes the set out of the processing bath using the holders and transfers the set to the standby bath, and
wherein the second transferer takes the set out of the standby bath using the holders and transfers the set to the first deliverer.

6. The substrate processing apparatus of claim 1, further comprising a lot transferer configured to transfer a lot including a plural number of the set to the immersion processor,
wherein the first transferer receives one set of the plural number of the set included in the lot transferred to the immersion processor by the lot transferer from the lot transferer, immerses the one set in the processing liquid of the immersion processor, takes the one set out of the immersion processor, transfers the one set to the standby bath, and immerses the one set in the rinsing liquid of the standby bath.

7. The substrate processing apparatus of claim 1, wherein the single-wafer processor is a liquid processor configured to process one substrate of the one or more substrates with a chemical liquid and dry the one substrate after processing.

8. The substrate processing apparatus of claim 1, wherein the single-wafer processor includes a plurality of single-wafer processors,
wherein each of the plurality of single-wafer processors includes:
a liquid processor configured to process one substrate of the one or more substrates with liquid; and
a drying processor configured to dry the one substrate with a supercritical fluid, and
wherein the third transferer takes the one substrate out of the liquid processor, transfers the one substrate to the drying processor, takes the one substrate out of the drying processor, and transfers the one substrate to the second deliverer.

9. A substrate processing method used in a substrate processing apparatus,
wherein the substrate processing apparatus includes:
an immersion processor configured to collectively immerse a set of one or more substrates in a processing liquid and process the set;
a standby bath configured to immerse the set processed by the immersion processor in a rinsing liquid and cause the set to be in a waiting state;
a first transferer configured to transfer the set from the immersion processor to the standby bath;
a first deliverer configured to accommodate the set after being immersed in the rinsing liquid in the standby bath;
a second transferer configured to transfer the set from the standby bath to the first deliverer;
a single-wafer processor configured to process the one or more substrates included in the set one by one;
a second deliverer configured to accommodate the one or more substrates processed by the single-wafer processor; and
a third transferer configured to transfer the one or more substrates one by one between the first deliverer, the single-wafer processor, and the second deliverer,
the substrate processing method comprising:
executing a series of substrate processes including an immersion process performed by the immersion processor, a first transfer process of transferring the set from the immersion processor to the first deliverer via the standby bath, a second transfer process of transferring the one or more substrates from the first deliverer to the single-wafer processor, a single-wafer process performed by the single-wafer processor, and a third transfer process of transferring the one or more substrates from the single-wafer processor to the second deliverer,
wherein the executing the series of substrate processes includes:
determining a start timing of the immersion process for a subsequent set, based on a cumulative time of the second transfer process, the single-wafer process, and the third transfer process for the set; and
starting the immersion process for the subsequent set at the start timing determined in the determining the start timing.
